(19) United States
(12) Patent Application Publication
(10) Pub. No.: US 2026/0304629 A1
(43) Pub. Date: Oct. 1, 2026

(54) COIL ARRANGEMENT FOR POWER STAGE MODULE

(71) Applicant: TEXAS INSTRUMENTS INCORPORATED, Dallas, TX (US)

(72) Inventors: Evan Reutzel, Center Valley, PA (US); Sudhir Nagaraj, Dallas, TX (US)

(21) Appl. No.: 19/093,317

(22) Filed: Mar. 28, 2025

(51) Int. Cl. H05K 1/18; H05K 1/02; H05K 1/09

(52) U.S. Cl. CPC H05K 1/181; H05K 1/0203; H05K 1/09

(57) ABSTRACT

An electronic structure comprising a substrate, chips, first conductive segments, second conductive segments, third conductive segments, and a conductive trace. The substrate has a first row of contacts and a second rows of contacts. The chips are arranged in a first row and a second row on the substrate. The chips in the first row and the second row have output terminals coupled to the first and second row of contacts respectively. The first conductive segments and the second conductive segments both extend away from a surface of the substrate and away from the first row of contacts and the second row of contacts respectively. The third conductive segments extend from respective first conductive segments to respective second conductive segments. Respective third conductive segments include linear segments extending over the chips. The conductive trace is over the chips and over or under the third conductive segments.

### BACKGROUND

Power stage modules are used to convert a first voltage value to a second voltage value. A commonly used power stage architecture is the trans-inductance voltage regulator (TLVR). The TLVR architecture includes transformers coupled between stages to have a better transient response.

### SUMMARY

Some aspects relate to an electronic structure including a substrate, chips, first conductive segments, second conductive segments, third conductive segments, and a conductive trace. The substrate has a first row of contacts and a second row of contacts. The chips are arranged in a first row and a second row on the substrate. The chips in the first row have outputs terminals coupled to the first row of contacts, and the chips in the second row have outputs terminals coupled to the second row of contacts. The first conductive segments extend away from a surface of the substrate and away from the first row of contacts. The second conductive segments extend away from the surface of the substrate and away from the second row of contacts. The third conductive segments extend from respective first conductive segments of the first conductive segments to respective second conductive segments of the second conductive segments. Respective third conductive segments of the third conductive segments include linear segments extending over the chips. The conductive trace is over the chips and over or under the third conductive segments. The conductive trace has a serpentine shape.

Some aspects relate to a device including a substrate, a first row of power stage chips, a second row of power stage chips, first conductive bridges, and second conductive bridges. The substrate has a first edge and a second edge opposite the first edge. The first row of power stage chips are over the substrate, and have first ouput terminals that are adjacent to the first edge. The second row of power stage chips are between the first row of power stage chips and the second edge. The second row of power stage chips have second output terminals that are adjacent to the second edge. The first conductive bridges have respective base regions that are coupled to the first output terminals of the first row of power stage chips. The respective conductive bridges of the first conductive bridges extend over respective power stage chips of the first row. The second conductive bridges have respective base regions that are coupled to the second output terminals of the second row of power stage chips. The respective conductive bridges of the second conductive bridges extend over respective power stage chips of the second row.

Further, some aspects relate to a system including a motherboard, a first electronic structure, a second electronic structure, a controller, and a chip. The first electronic structure is over the motherboard. The first electronic structure has a control terminal and an output terminal. The first electronic structure comprises first linear conductive segments and a first serpentine conductive trace within a first magnetic fill material. The second electronic structure is over the motherboard. The second electronic structure has a control terminal and an output terminal. The output terminal of the second electronic structure is coupled to the output terminal of the first electronic structure. The second electronic structure comprises second linear conductive segments and a second serpentine conductive trace within a second magnetic fill material. The controller is over the motherboard. The controller has output terminals coupled to the control terminals of the first electronic structure and the second electronic structure. The chip is over the motherboard. The chip has an input terminal coupled to the output terminals of the first electronic structure and the second electronic structure.

### BRIEF DESCRIPTION OF THE DRAWINGS

FIG. 1 shows an isometric view of a chip assembly having multiple conductive segments.

FIG. 2 shows a top-down view of the chip assembly shown in FIG. 1.

FIG. 3 shows a side view of the chip assembly shown in FIG. 1.

FIG. 4 shows another side view of the chip assembly shown in FIG. 1.

FIG. 5 shows a cross section taken from the chip assembly shown in FIG. 1.

FIG. 6 shows another cross section taken from the chip assembly shown in FIG. 1.

FIG. 7 shows an isometric view of another example chip assembly.

FIG. 8 shows an isometric view of another example chip assembly.

FIG. 9 shows an example circuit schematic for the chips in the chip assembly.

FIG. 10 shows a top-down view of the chip assembly having elements hidden to see the location of the chips.

FIG. 11 shows a circuit diagram illustrating coupling between multiple chip assemblies and their control.

FIG. 12 shows an isometric view of another example chip assembly.

FIG. 13 shows a top-down view of the chip assembly shown in FIG. 12.

FIG. 14 shows a side view of the chip assembly shown in FIG. 12.

FIG. 15 shows an isometric view of another example chip assembly.

FIG. 16 shows a top-down view of the chip assembly shown in FIG. 15.

FIG. 17 shows a side view of the chip assembly shown in FIG. 15.

FIG. 18 shows a DC-DC converter coupled to a load on a motherboard.

### DETAILED DESCRIPTION

Voltage regulators are devices used to convert an input voltage value to an output voltage value. A specific kind of voltage regulator, a trans-inductance voltage regulator (TLVR), has a desirable transient response due to the use of multiple transformers coupling between different power stages. The need for conductive segments to connect adjacent transformers results in excessive length and complexity. This excess length can lead to increased size and weight of the assembly, reduced efficiency due to increased resistance, and higher costs associated with materials and labor.

Thus, A TLVR configuration is provided, featuring adjacent transformers coupled together via a serpentine-shaped conductive trace that follows the grid pattern of the underlying chip layout. This arrangement optimizes space utilization by alternating the current flow through the transformers.

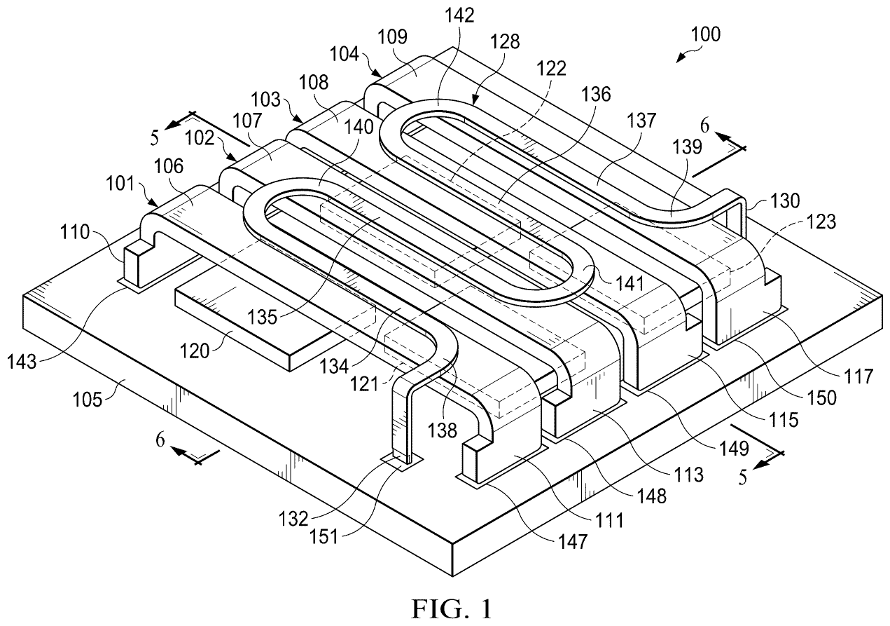

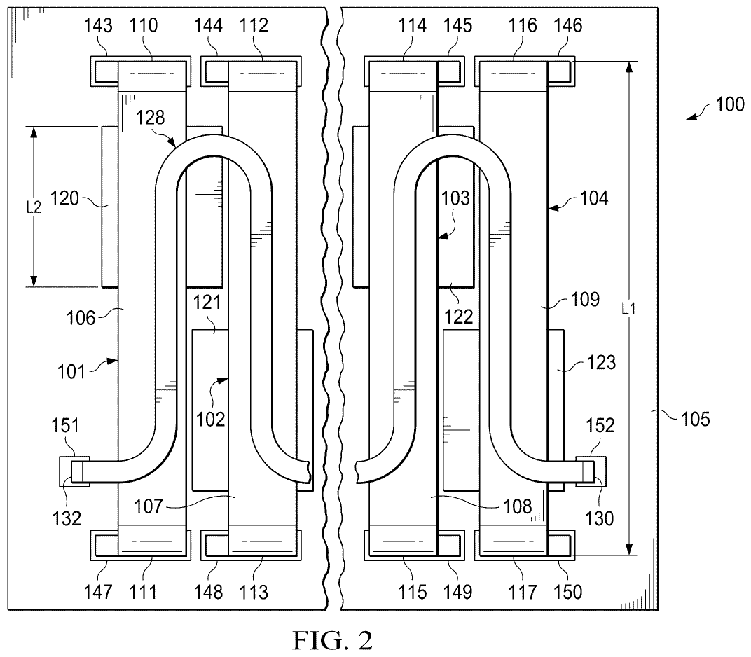

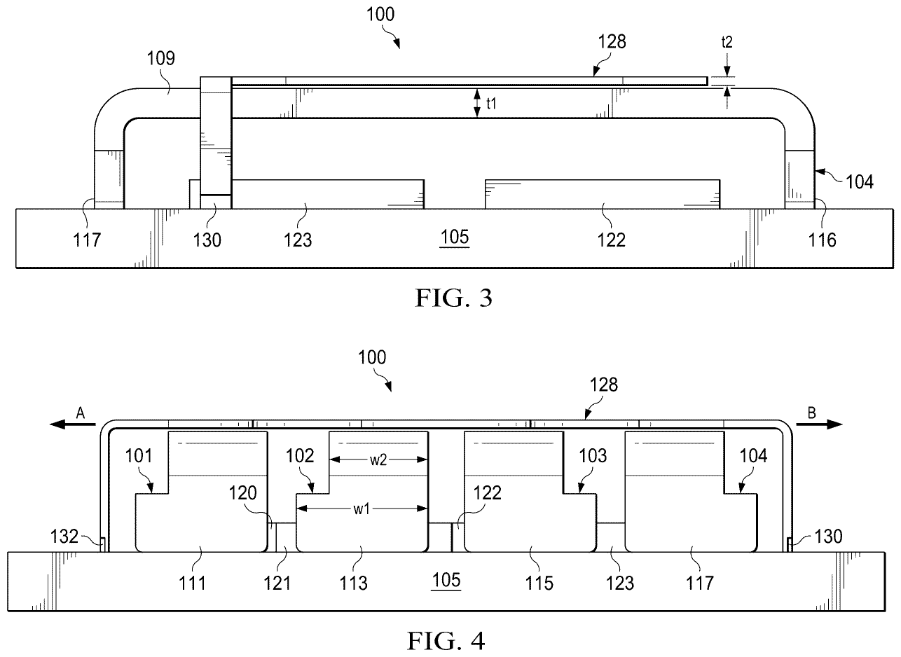

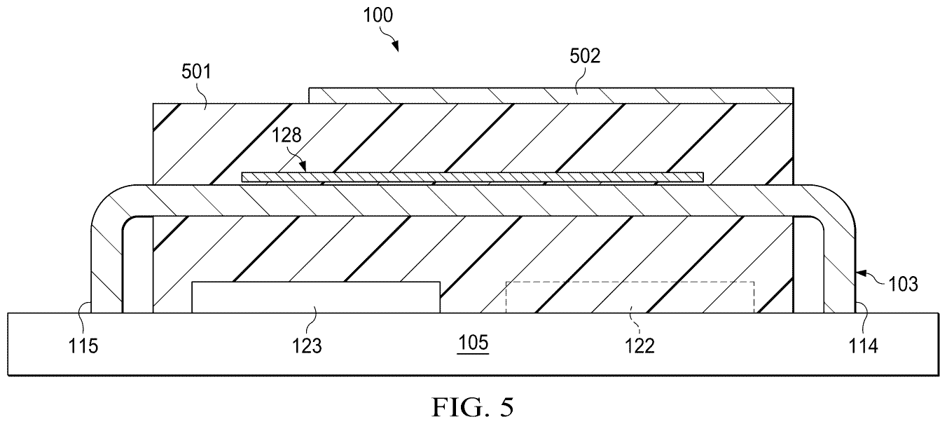

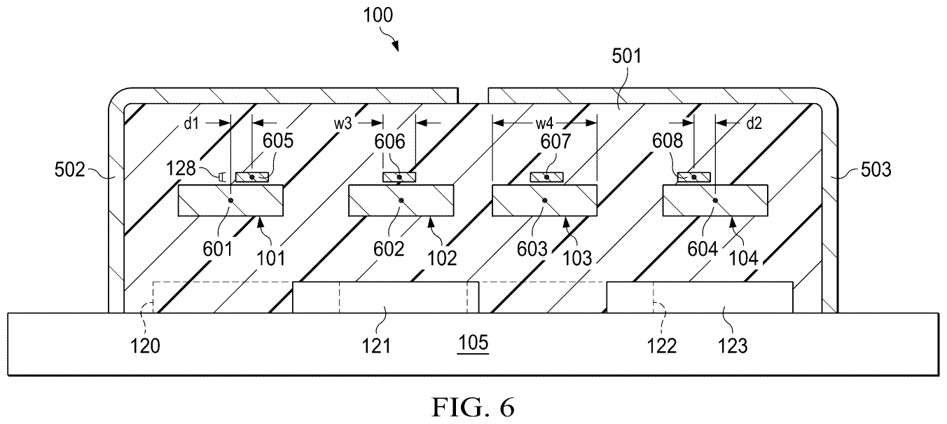

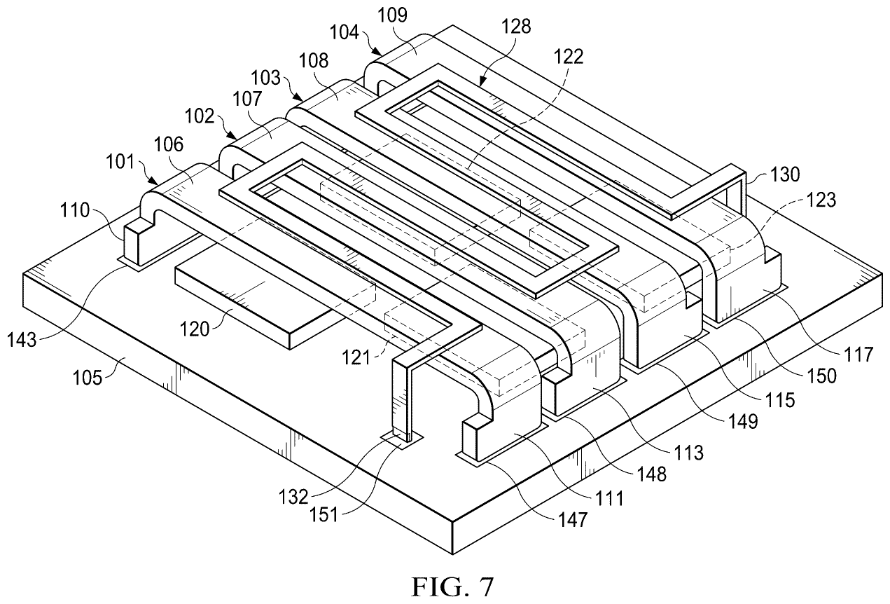

FIGS. 1-6 show different views of a TLVR chip assembly 100. FIG. 1 shows an isometric view, FIG. 2 shows a top view, FIG. 3 shows a side view, FIG. 4 shows another side view, FIG. 5 shows a cross section view, and FIG. 6 shows another cross section view.

The TLVR chip assembly 100 includes a substrate 105, a first integrated circuit chip 120, a second integrated circuit chip 121, a third integrated circuit chip 122, a fourth integrated circuit chip 123, a first conductive bridge 101, a second conductive bridge 102, a third conductive bridge 103, a fourth conductive bridge 104, a conductive trace 128, and contacts 143-152. The integrated circuit chips 120-123 may also be referred to as power stage chips, and the conductive trace 128 may also be referred to as a serpentine trace.

FIG. 1 shows an isometric view of the TLVR chip assembly 100. FIG. 1 includes callouts for cross sections 5 and 6 which are shown in FIGS. 5 and 6 respectively. The first integrated circuit chip 120, the second integrated circuit chip 121, the third integrated chip 122, and the fourth integrated circuit chip 123 are visible from this view. The first conductive bridge 101 has a first conductive segment 110, a second conductive segment 111, and a third conductive segment 106. The third conductive segment 106 extends from the first conductive segment 110 to the second conductive segment 111. The first conductive segment 110 and the second conductive segment 111 extends away from the substrate 105 and each include a curved region that couples to the third conductive segment 106. The curved regions include a 90 degree bend from a normal direction from the substrate 105 to a tangential direction from the substrate 105. Thus, the first conductive bridge extends from one side of the TLVR chip assembly 100 to another side of the TLVR chip assembly 100. The first conductive bridge 101 also extends over the first integrated circuit chip 120 such that the first conductive bridge 101 is in front of the first integrated circuit chip 120 when viewed from a top-down view.

The first conductive bridge 101 is a single continuous conductive structure. The single continuous conductive structure has at least two bends to resemble the shape of a bridge. Additionally, the single continuous conductive structure may have a varying width such that the width of “leg” portions of the single continuous conductive structure may be wider.

The conductive bridges 102-104 also have respective first and second conductive segments 112-117 and third conductive segments 107-109, and extend over respective integrated circuit chips 121-123. The first and second conductive segments 110-117 may be referred to as first and second legs respectively or as base regions. The first and second conductive segments 110-117 are coupled to the substrate through contacts 143-150. The third conductive segments may be referred to as bodies. The conductive trace 128 is positioned overtop the conductive bridges 101-104 meaning that from a top-down view, the conductive bridges 101-104 are behind the conductive trace 128. The conductive trace 128 extends in a serpentine shape above the substrate 105. The conductive trace 128 has conductive columns 130 and 132 which couple the conductive trace 128 to the substrate 105 thought contacts 151-152. The conductive trace 128 has linear segments 134-137 over respective conductive segments 106-109 of the conductive bridges 101-104. The linear segments 134-137 of the conductive trace are also conductive segments. The conductive trace 128 also has first curved segments 138-139, and second curved segments 140-142. The first curved segments include 90 degree bends in a direction tangential to a top surface of the substrate 105. The second curved region include 180 degree bends in a direction tangential to a top surface of the substrate 105. The conductive segments 106-109 all extend in the same direction. The conductive columns 130 and 132 are also conductive segments of the conductive trace 128. The conductive bridges 101-104 and the conductive trace 128 may comprise a conductive material. For example, the conductive segments 110-111 and 106 may comprise copper or any other suitable conductive material.

The substrate 105 may comprise a plurality of stacked layers of epoxy resin polymer having conductive traces extending through it. The substrate 105 may comprise a layered structure consisting of multiple alternating layers of epoxy resin polymer, which can provide electrical insulation and mechanical support to the semiconductor devices. Each layer of epoxy resin polymer may be formed through a separate molding or deposition process, allowing for precise control over the material properties and thickness of each individual layer. The layers of epoxy resin polymer may be interspersed with conductive traces that extend through one or more of the layers, forming interconnects between different components or circuits on the substrate 105. These conductive traces can be formed using various techniques, such as electroplating, screen printing, or etching, and may comprise materials like copper, aluminum, or silver. In some examples, the layers of epoxy resin polymer may alternatively comprise a thermoplastic such as acrylonitrile butadiene fluorine (ABF).

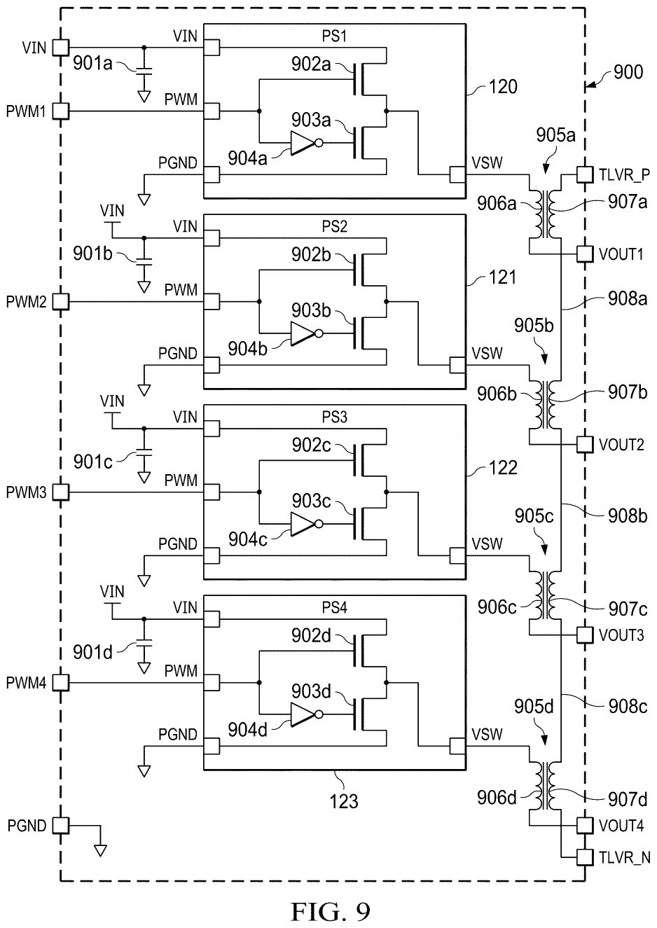

The TLVR chip assembly 100 receives an input voltage and provides an output voltage. When in operation, the integrated circuit chips 120-123 switch their outputs at a frequency to allow current to flow through respective conductive bridges 101-104. The combination of the conductive bridges 101-104 and the conductive trace 128 functions as transformers at the switching frequency such that each linear segment of the conductive trace 128 functions as a secondary coil that is magnetically coupled to the conductive bridges 101-104. See e.g., FIG. 9, discussed further herein. The functionality as a transformer allows a faster transient response as the outputs of the integrated circuit chips 120-123 are coupled through respective conductive bridges 101-104 and the conductive trace 128.

The geometry of this layout of the integrated circuit chips 120-123, the conductive bridges 101-104, and the conductive trace 128 provide an advantageous routing to achieve desired transient response in a small package. This advantage comes from the combination of the integrated circuit chips 120-123 positioned in a grid pattern and the alternating direction of the current flows on the conductive bridges 101-104 to reduce any unnecessary lengths of the conductive trace 128. The alternating direction of the current flowing on the conductive bridges 101-104 provides a streamlined ability to couple secondary windings to maximize power density. Additionally, the conductive trace 128 is a single continuous conductive material, which enables the conductive trace 128 to be fully enclosed, besides two terminals, within magnetic material (e.g., magnetic fill material 501 shown in FIG. 5). The conductive trace 128 being fully enclosed advantageously increases the magnetic coupling between the conductive trace 128 and the conductive bridges 101-104.

FIG. 2 shows a top view of the TLVR chip assembly 100 of FIG. 1. From this view, the first integrated circuit chip 120, the second integrated circuit chip 121, the third integrated circuit chip 122, and the fourth integrated circuit chip 123 are visible. The conductive bridges 101-104 have a first length (e.g., L1), and integrated circuit chips 120-123 have a second length (e.g., L2). The lengths L1, L2 relate to each other such that the length L1 is at least twice the length of L2 so that the conductive bridges 101-103 can extend the length of two integrated circuit chips. FIG. 2 also shows that the TLVR chip assembly 100 can be extended with the ellipses added. For example, a designer may choose to implement an integer number, n, integrated circuit chips and continue the pattern of the conductive bridges and the conductive trace. The integer number n may be between 2 and 100, or alternatively between 4 and 16, or any other suitable integer number. The number of conductive bridges may be equal to the number of integrated circuit chips to continue the pattern.

There is a tradeoff between the number of integrated circuit chips 120-123, their respective conductive bridges 101-104, and the transient response. More integrated circuit chips and conductive bridges with the conductive trace leads to a better transient response. While less integrated circuit chips, less conductive bridges, and a smaller conductive trace would use less area and have a smaller package.

FIG. 3 shows a side view of the TLVR chip assembly 100. This side view shows that the third integrated circuit chip 122 in front of the first integrated circuit chip 120, and that the fourth integrated circuit chip 123 in front of the second integrated circuit chip 121. Thus, the first integrated circuit chip 120 and the second integrated circuit chip 121 are not visible from this view. Similarly, only the fourth conductive bridge 104 is shown as the other conductive bridges 101-103 are behind the fourth conductive bridge 104. This view shows the thickness of the conductive bridges 101-103 as t1. This view also shows the thickness of the conductive trace 128 as t2. The value for t2 is shown as being less than the value for t1. Alternatively, t1 and t2 may have different values. For example, t1/t2 may be between 0.1 to 10, or between 0.2 to 1. Thus, the value for t 2 may be equal or even larger than t1.

FIG. 4 shows the TLVR chip assembly 100 from another side view. This view depicts the conductive segments (e.g., 111, 113, 115, 117) with the other conductive segments obscured behind. Each of the conductive bridges 101-104 comprises two conductive legs (e.g., conductive segment 110 and conductive segment 111 for conductive bridge 101) extending upward from the substrate 105. These conductive segments exhibits two distinct widths: a wider section having a width w1 located nearest to the substrate 105 contact region, and a narrower section having a width w2 located near the connection point with a designated body (e.g., conductive segment 106). The conductive segments 110-117 of the conductive bridges 101-104 exhibit a mirrored configuration. For example, conductive bridge 101 has conductive segments 111 and 110 that mirror each other in width from front to back along the conductive segment 106 (See FIG. 1). These conductive segments 110-117 are also mirrored from left to right in FIG. 4. For example, the conductive segments 110-113 of conductive bridge 101 and conductive bridge 102 feature their wider sections oriented in a first direction (Direction A), while conductive segments 114-117 of conductive bridges 103 and 104 orient their wider sections in an opposite second direction (Direction B). This mirroring pattern extends to all four conductive bridges, ensuring a symmetrical arrangement. This symmetrical arrangement may continue if more bridges are used.

FIG. 5 shows a cross section of the TLVR chip assembly 100. This view also includes magnetic fill material 501 and heat sink 502. The conductive bridges 101-104 and the conductive trace 128 are disposed within the magnetic fill material 501. The magnetic fill material 501 may comprise an epoxy resin having ferromagnetic particles suspended throughout. The ferromagnetic particles may be made of iron, nickel, cobalt, or combination thereof. The magnetic fill material increases the permeability to increase the magnetic coupling between the conductive bridges 101-104 and the conductive trace 128. The heat sink 502 is shown being positioned along an outer surface of the TLVR chip assembly 100. The heat sink 502 may comprise copper or another suitable thermally conductive material or assembly. The heat sink 502 advantageously provides a high thermal conductivity to remove heat generated within the TLVR chip assembly 100.

FIG. 6 shows another cross section of the TLVR chip assembly 100. This cross section includes the magnetic fill material 501 and heat sink 502, and further includes another heat sink 503. The heat sinks 502-503 may extend over multiple surfaces of the TLVR chip assembly 100. For example, the heat sinks 502-503 are shown extending over a top surface and two side surfaces. The heat sinks 502-503 may also extend over a bottom surface or other side surfaces. The conductive trace 128 is positioned above conductive bridges 101-104. Respective centers 605, 608 of respective segments of the conductive trace 128 are offset from respective center (e.g., 601, 604) of conductive bridge 101 and conductive bridge 102 by distances d1 and d2. Distances d1 and d2 have a ratio, d1/d2, that may be within 80%-120%, or between 90%-110%. Respective centers 606, 607 of respective segments of the conductive trace 128 are directly aligned with the centers 602, 603 of conductive bridges 102 and 103. The widths of the conductive trace are w3, and the width of the conductive bridges is w4 (e.g., conductive bridge 103). The value of w3 may be less than w4, or alternatively may be equal to w4. A ratio, w3/w4, may be between, for example, 0.2-2, or be between 0.5-1. Thus, other widths of the conductive bridges 101-104 and the conductive trace 128 may be used. The geometrical arrangement may advantageously increase magnetic coupling because excess distance between segments of the conductive trace 128 is reduced while still maintaining the desire magnetic coupling. The magnetic fill material 501 and heat sinks 502-503 cover over other elements, so are hidden in other views for illustrative purposes.

FIG. 7 shows another example of the TLVR chip assembly 100 of FIG. 1. In this example, the conductive trace 128 has square corners instead of rounded corners. Other geometries for the corners may also be used, for example, three 30 degree turns or two 45 degree turns. The different geometries may be advantageously cheaper or easier to manufacture, or have desired coupling characteristics by minimizing high electric or magnetic field spots.

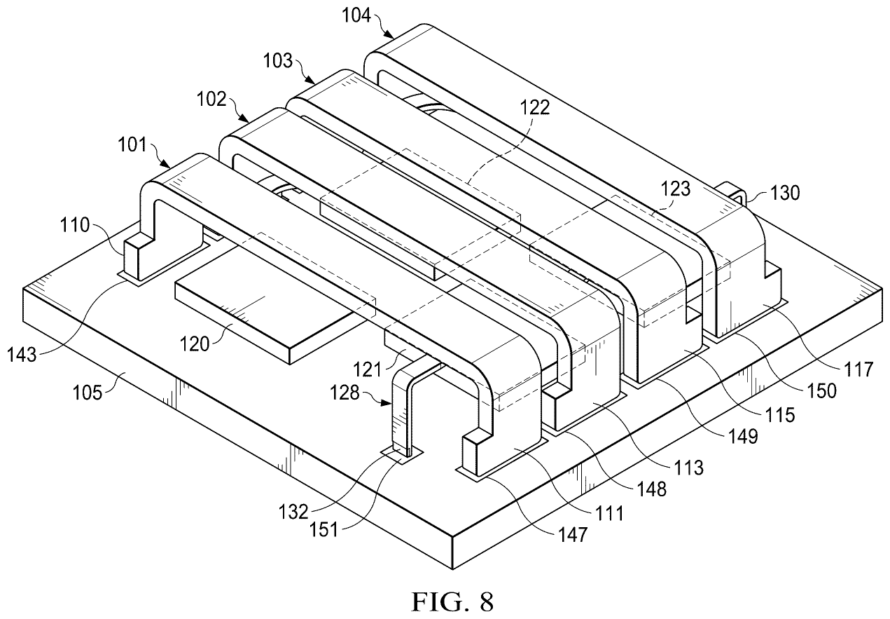

FIG. 8 shows an alternative example of the TLVR chip assembly. In this example, the conductive trace 128 is positioned under the conductive bridges 101-103. Thus, the conductive trace 128 may have linear segments under the conductive segments 106-109 of the conductive bridges 101-104. The conductive bridges 101-103 may have an increased height to enable the conductive trace 128 to be positioned under the conductive bridges 101-103.

FIG. 9 shows an example circuit diagram 900 resembling the TLVR chip assembly 100. The circuit diagram 900 includes inputs for voltage (VIN), pulse-width modulation signal 1 (PWM1), pulse-width modulation signal 2 (PWM2), pulse-width modulation signal 3 (PWM3), pulse-width modulation signal 4 (PWM4), and power ground (PGND). The circuit diagram 900 also has output connections: trans-inductance voltage regulator positive (TLVR_P), trans-inductance voltage regulator negative (TLVR_N), voltage output 1 (VOUT1), voltage output 2 (VOUT2), voltage output 3 (VOUT3), and voltage output 4 (VOUT4). Each of the integrated circuit chips 120-123 include an input voltage terminal (VIN), a pulse-width modulation input (PWM), and a power ground input (PGND). Each of the integrated circuit chips further include a voltage switch (VSW) output. Capacitors 901a-901d couple the input voltage of the circuit diagram to the input voltage (VIN) of respective integrated circuit chips 120-123. Transformers 905a-905d couple respective voltage switch outputs (VSW) of the integrated circuit chips 120-123 to each other and to the voltage outputs 1-4.

Each of the integrated circuit chips 120-123 have respective first transistors 902a-902d, second transistors 903a-903d, and inverters 904a-904d. The first transistors 902a-902d have first terminals coupled to respective input voltage terminals (VIN), control terminals coupled to respective pulse width modulation inputs (PWM), and second terminals coupled to respective voltage switch outputs (VSW). The second transistors 903a-903d have first terminals coupled to respective second terminals of the first transistors 902a-902d, control terminals coupled to outputs of respective inverters 904a-904d, and second terminals coupled to respective ground terminals (PGND). The inverters 904a-904d have respective inputs coupled to respective pulse width modulations inputs (PWM).

The transformers 905a-905d include primary windings 906a-906d and secondary windings 907a-907d. The primary windings 906a-906d are a circuit representation of the conductive segments 106-109 of the conductive bridges 101-104, and the secondary windings 907a-907d are a circuit representation of the linear segments 134-137 of the conductive trace 128. For example, the first transformer 905a has a primary coil that is realized by the first conductive bridge 101, and has a secondary coil that is realized by a linear segment of the conductive trace 128 that is directly over the conductive bridge 101. Thus, the first conductive bridge 101 couples the voltage switch output (VSW) of the first integrated circuit chip 120 to the first output voltage terminal (VOUT1) of the circuit diagram 900. The secondary coils of the transformers 905a-905d are all coupled together by connections 908a-908c. The connections are a circuit representation of the curved segments 140-142 of the conductive trace 128.

The transistors 902a-902d and 903a-903b are shown as being a MOSFET, but other suitable transistor technologies are also applicable. For example, the transistors 902a-902d may alternatively be bipolar junction transistors (BJTs).

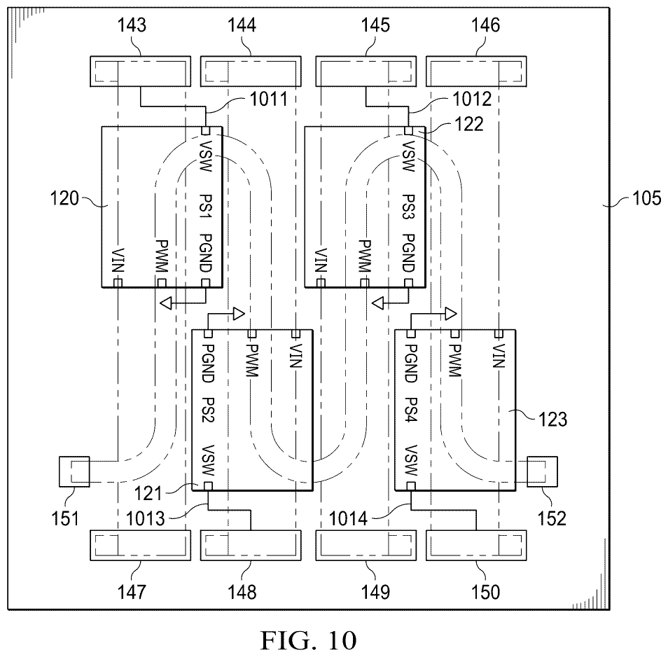

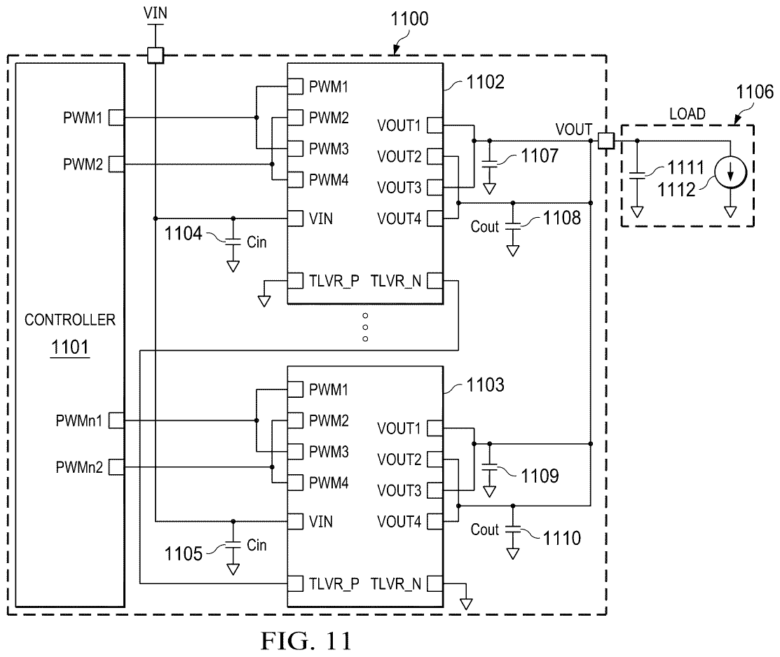

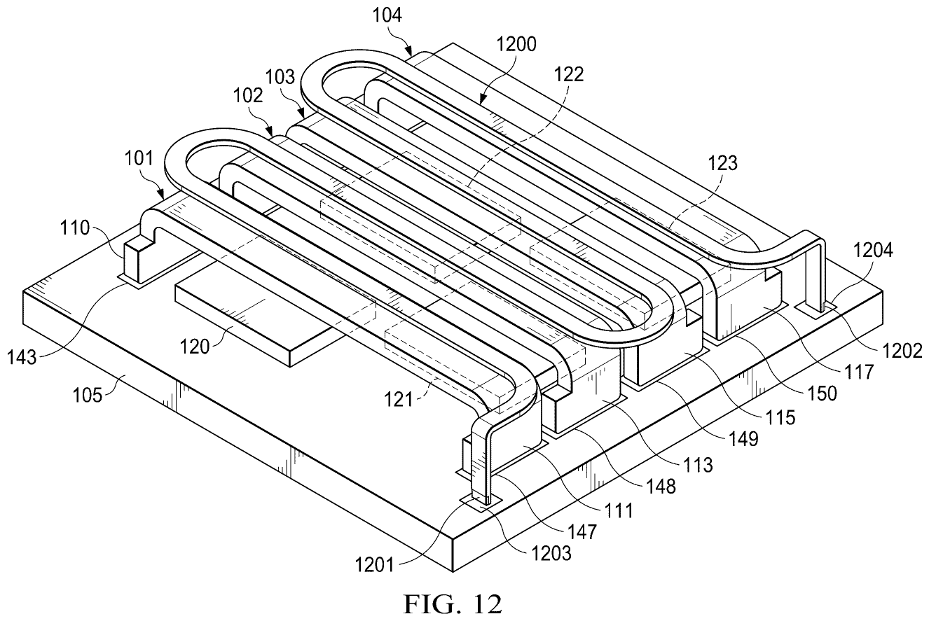

FIG. 10 shows an example of how the integrated circuit chips 120-123 are arranged over the substrate 105, and how the integrated circuit chips 120-123 are coupled to the conductive bridges 101-104. The integrated circuit chips 120-123 are arranged in two rows. A first row of the integrated circuit chips 120, 122 are nearest to a first edge of the substrate, and a second row of the integrated circuit chips 121, 123 are nearest to a second edge of the substrate. The integrated circuit chips 120, 122 in the first row are offset from the integrated circuit chips 121, 123 in the second row. The conductive bridges 101-104 and the conductive trace 128 are shown by dotted line so that the integrated circuit chips 120-123 can be seen under them. This view also includes conductive contacts 1001-1008 which couple the integrated circuit chips 120-123 to the conductive bridges 101-104. The conductive columns 130 and 132 extend from ends of the conductive trace 128 to contacts 1009-1010 on the substrate 105. The contacts 1009-1010 represent the output connections TLVR_N and TLVR_P of the circuit shown in FIG. 10. The conductive contacts 143-150 are arranged in two rows. For example, contacts 143-146 may be a first row, and contacts 147-150 may be the second row. The number of conductive contacts 143-150 shown is 8. The structure may be extended to include more conductive contacts. For example, there may be between 2-80 conductive contacts, or between 4-20 conductive contacts. The PWM inputs of the integrated circuit chips 120-123 may be coupled to a controller, for example, as shown in FIG. 11.

The integrated circuit chips 120-123 have voltage switch terminals (VSW) coupled to alternating conductive contacts (e.g., 143 and 148) through conductive metal traces 1011-1014 of the substrate 105. Because the voltage switch terminals (VSW) couple to alternating conductive contacts, the conductive contacts (e.g., 147 and 144) on opposite sides correspond to the voltage output terminals of the circuit diagram 900 (e.g., VOUT1-VOUT4). This alternating pattern enables current to flow through the conductive bridges 101-104 in alternating directions between the integrated circuit chips 120-123. For example, current will flow down from contact 143 to contact 147 through conductive bridge 101, and current will flow up from contact 148 to contact 144 through conductive bridge 102. The current flowing in alternating directions enables the conductive trace 128 to have turns and serpentine over the conductive bridges 101-104 so that the current flowing through the conductive trace 128 will be in the same direction as the conductive bridge underneath. For example, the current through conductive bridge 101 will induce a current going down in the overlying segment of the conductive trace 128, and the current through conductive bridge 102 will induce a current going up in the overlying segment of the conductive trace 128. Thus, this design minimizes excess length of the conductive trace 128.

FIG. 11 shows a DC-DC converter circuit 1100 that resembles how multiple TLVR chip assemblies 1102-1103 may be used together to obtain more stages. The DC-DC converter circuit 1100 includes a controller 1101, a first TLVR chip assembly 1102, a second TLVR chip assembly 1103, a first capacitor 1104, a second capacitor 1105, a load 1106, a third capacitor 1107, a fourth capacitor 1108, a fifth capacitor 1109, and a sixth capacitor 1110. Each of the TLVR chip assemblies 1102-1103 have an electronic structure as shown in FIGS. 1-6 or any of the other examples disclosed.

The controller 1101 has a two pulse width modulation outputs (e.g., PWM1 and PWM2) for each TLVR chip assembly (e.g., 1102). The TLVR chip assemblies 1102-1103 have the same input and output terminals as shown in FIG. 9. The TLVR chip assemblies have their trans-inductance voltage regulator terminals coupled so as to form a complete loop between their respective conductive traces. For example, TLVR_N of chip assembly 1102 is coupled to TLVR_P of chip assembly 1103. The capacitors (e.g., 1104) are coupled to respective voltage inputs and voltage outputs of the TLVR chip assemblies 1102 (e.g., VIN of chip assembly 1102) to smooth any voltage noise. The outputs of the TLVR chip assemblies 1102-1103 are coupled together and coupled to the voltage output terminal of the DC-DC converter circuit 1100. The DC-DC converter circuit 1100 may be coupled to a load 1106. The load is shown modeled as a capacitor 1111 and current drain 1112. The load may be a single processor, such as a microprocessor or graphic processor unit (GPU), or it may comprise multiple processors, including those found in a server farm. A server farm typically comprises numerous modules, each supporting one or more processors, thereby increasing the overall computational capacity and potential load on the system.

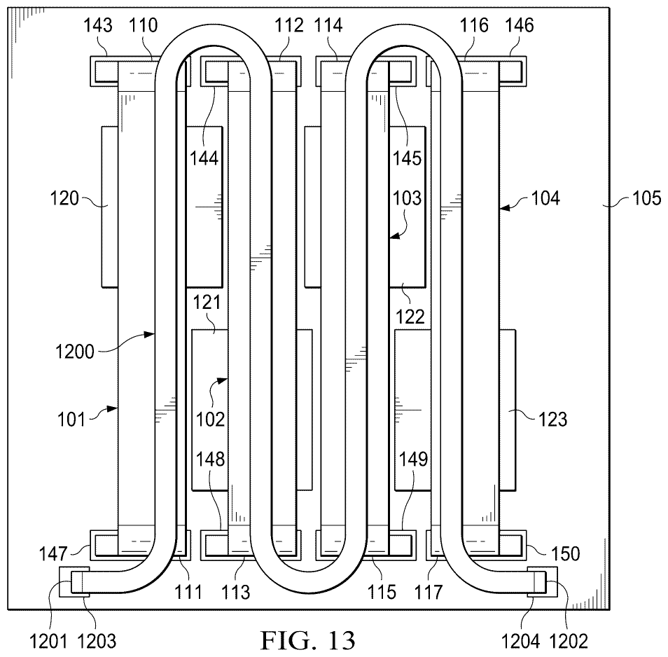

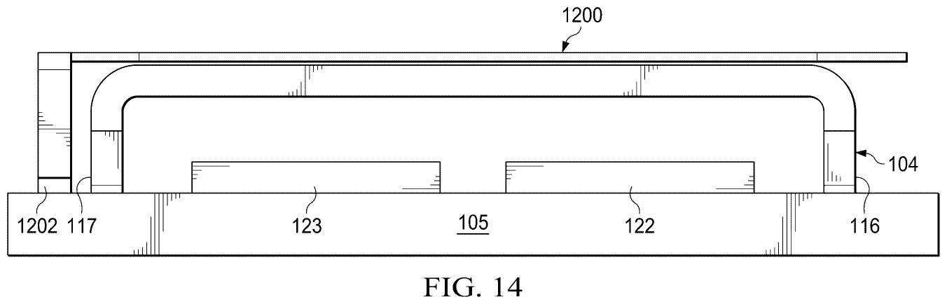

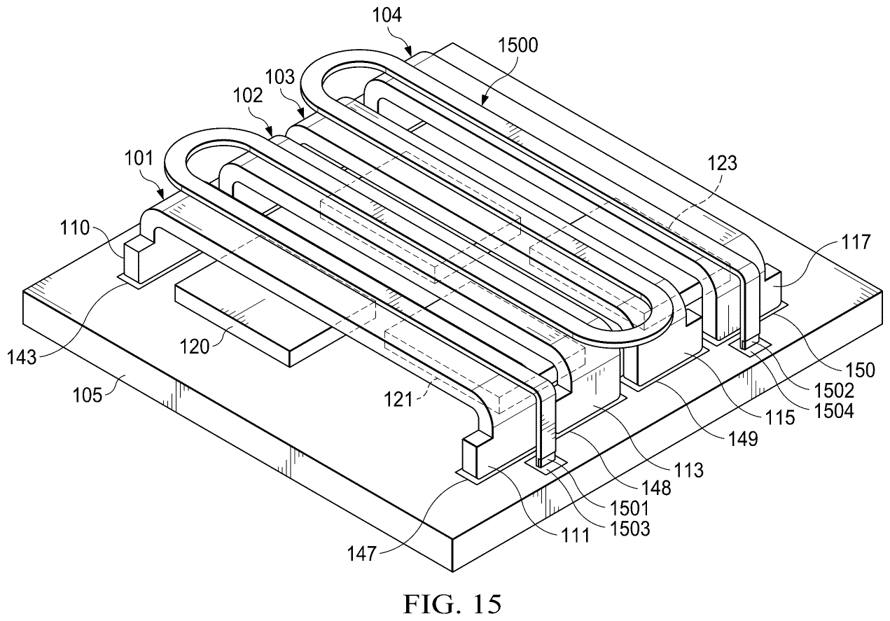

FIGS. 12-14 show a second example of a TLVR chip assembly from an isometric view, a top view, and a side view respectively. This TLVR chip assembly includes a substrate 105, conductive bridges 101-104, and integrated circuit chips 120-123 as described in FIGS. 1-6. FIG. 12 shows an isometric view of the TLVR chip assembly where the conductive trace 1200 has been changed to have conductive columns 1201-1202 that have been moved to be outer corners of the substrate 105 to couple to contacts 1203-1204. This position of the conductive columns 1201-1202 advantageously increase the coupling between the conductive bridges 101-104 and the conductive trace 1200 because the conductive trace 1200 has bends towards the substrate 105 to terminate at contacts 1203-1204 that are closer to the conductive bridges 101-104.

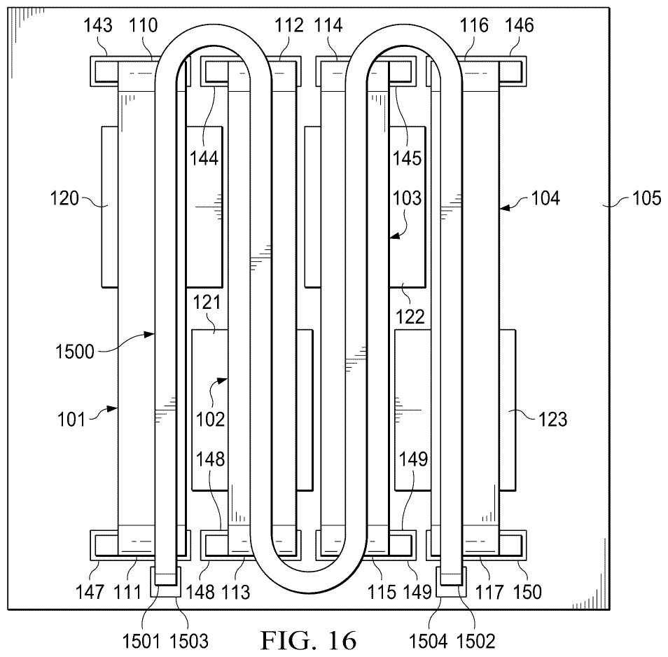

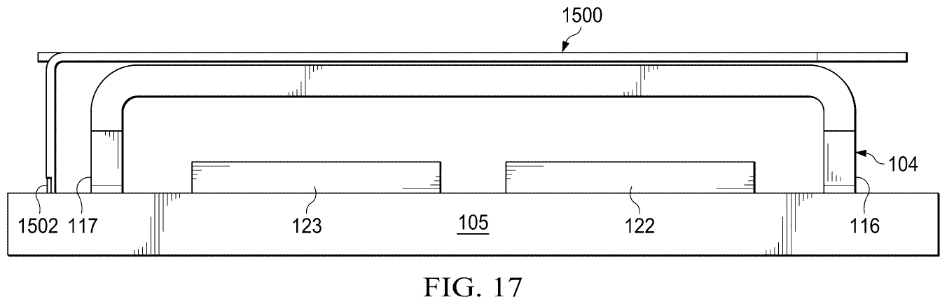

FIGS. 15-17 show a third example of a TLVR chip assembly from an isometric view, a top view, and a side view respectively. This TLVR chip assembly includes a substrate 105, conductive bridges 101-In this third example, the conductive trace 1500 has been changed to have their conductive columns 1501-1502 extend past the conductive bridges 101-104 and terminate in line with the conductive bridges 101-104 at conductive contacts 1503-1504. This position of the conductive columns 1501-1502 and the conductive trace 1500 further increases the coupling because the bends of the conductive trace 1500 are over the conductive bridges 101-104.

Among the examples discusses herein, the amount of coupling between the primary coils and the secondary coils can be changed by the termination points. This coupling can be referred to as a coupling coefficient. Similarly, the spacing between termination points can lead to different amounts of secondary leakage. For example, as the spacing decreases, the amount of secondary leakage increases. Thus, the coupling coefficient and the amount of second leakage between the conductive trace 1500 and the conductive bridges 101-104 becomes an important design parameter that can be used to optimize the overall design. For example, increasing the distance between termination points may increase the coupling coefficient, while decreasing the distance between termination points may decrease the amount of secondary leakage.

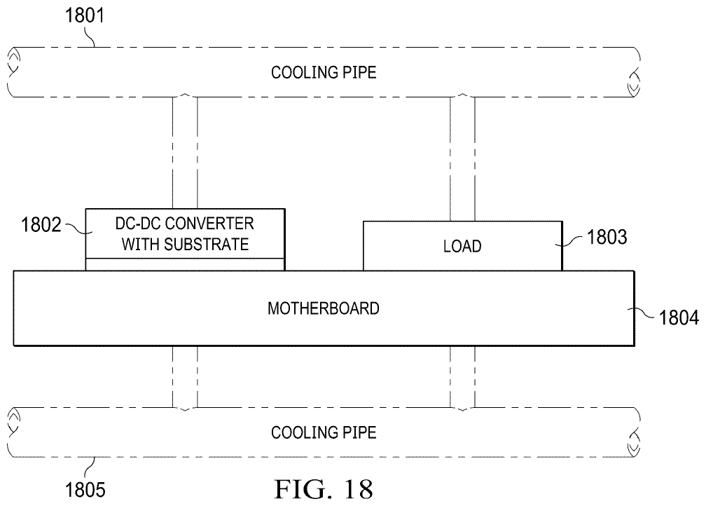

FIG. 18 shows an application of a DC-DC converter circuit 1802. The DC-DC converter circuit 1802 may be the DC-DC converter circuit 1100 shown in FIG. 11. For example, the DC-DC converter circuit 1802 may comprise multiple TLVR chips (e.g., 1102-1103) each having a serpentine-shaped conductive trace. Additionally, the DC-DC converter circuit 1802 receives an input voltage through the motherboard or from a connection similar to the VIN terminal of the DC-DC converter circuit 1100 shown in FIG. 11. The DC-DC converter circuit 1802 may be disposed on a motherboard 1804. Cooling pipes 1801, 1805 couple to the DC-DC converter circuit 1802 and the motherboard 1804. A load 1803 is disposed on the motherboard 1804. The load 1803 may be the load 1106 shown in FIG. 11. The DC-DC converter circuit 1802 may provide a stable output voltage to the load 1803. In some examples, the DC-DC converter circuit 1802 includes a substrate 105 closer to the motherboard 1804 and conductive bridges 101-103 closer to the cooling pipe 1801. In other examples, the DC-DC converter circuit 1802 may be disposed on a side of the motherboard 1804 opposite the load 1803, and the DC-DC converter circuit 1802 includes a substrate 105 closer to the motherboard 1804 and conductive bridges 101-103 closer to the cooling pipe 1805. The load 1803 may be referred to as a chip.

Example embodiments of the present disclosure are summarized here. Other embodiments can also be understood from the entirety of the specification and the claims filed herein.

Example 1. An electronic structure, comprising: a substrate having a first row of contacts and a second row of contacts; chips arranged in a first row and a second row on the substrate, the chips in the first row having output terminals coupled to the first row of contacts, and the chips in the second row having outputs terminals coupled to the second row of contacts; first conductive segments extending away from a surface of the substrate and away from the first row of contacts; second conductive segments extending away from the surface of the substrate and away from the second row of contacts; third conductive segments extending from respective first conductive segments of the first conductive segments to respective second conductive segments of the second conductive segments, where respective third conductive segments of the third conductive segments include linear segments extending over the chips; and a conductive trace over the chips and over or under the third conductive segments, where the conductive trace has a serpentine shape.

Example 2. The electronic structure of example 1, further including: a first conductive segment that extends between a first end of the conductive trace and a first contact on the substrate; and a second conductive segment that extends between a second end of the conductive trace and a second contact on the substrate.

Example 3. The device of Example 1, further including a magnetic fill material that at least partiality surrounds the conductive trace.

Example 4. The electronic structure of example 1 where chips in the first row are offset in a first direction relative to chips in the second row.

Example 5. The device of example 1, where the first conductive segment, the second conductive segment, the third conductive segment, and the conductive trace each comprise copper.

Example 6. The electronic structure of example 1, where the serpentine shape of the conductive trace includes linear segments, and where the linear segments of the conductive trace are over or under the third conductive segments and are arranged in the same direction with the linear segments of the third conductive segments.

Example 7. The electronic structure of example 1, further including: a first heat sink structure around the chips, the first conductive segments, the second conductive segments, the third conductive segments, and the conductive trace along a top surface, a first side surface, and a bottom surface; and a second heat sink structure around the chips, the first conductive segments, the second conductive segments, the third conductive segments, and the conductive trace along the top surface, a second side surface opposite the first side surface, and the bottom surface.

Example 8. The electronic structure of example 1, where a number of conductive segments in the third conductive segments is equal to a number of chips.

Example 9. A device comprising: a substrate having a first edge and a second edge opposite the first edge; a first row of power stage chips over the substrate, the first row of power stage chips having first output terminals that are adjacent to the first edge; a second row of power stage chips between the first row of power stages and the second edge, the second row of power stage chips having second output terminals that are adjacent to the second edge; first conductive bridges having respective base regions that are coupled to the first output terminals of the first row of power stage chips, the respective conductive bridges of the first conductive bridges extending over respective power stage chips of the first row; and a second conductive bridges having respective base regions that are coupled to the second output terminals of the second row of power stage chips, the respective conductive bridges of the second conductive bridges the first conductive bridge and extending over respective power stage chips of the second row.

Example 10. The device of example 9, where the first row of power stage chips extend in a first direction, and where the second row of power stage chips are staggered from the first row of power stage chips along the first direction.

Example 11. The device of example 9, where the first conductive bridges include a first conductive bridge and a second conductive bridge, where the second conductive bridges include a third conductive bridge, where the third conductive bridge is between the first conductive bridge and the second conductive bridge.

Example 12. The device of example 9, where the first conductive bridges and the second conductive bridges have lengths that are at least twice as long as a length of a power stage chip.

Example 13. The device of example 9, further including a serpentine trace positioned over the first conductive bridges and the second conductive bridges

Example 14. The device of example 13, where the serpentine trace has conductive segments extending over or under the first conductive bridges and the second conductive bridges, and the conductive segments of the serpentine trace are arranged in a same direction with the first conductive bridges and the second conductive bridges.

Example 15. The device of example 13, further including a magnetic fill material surrounding the first conductive bridges, the second conductive bridges, and the serpentine trace.

Example 16. The device of example 14, where the conductive segments of the serpentine trace have respective widths that are less than a width of the first conductive bridges.

Example 17. A system including a motherboard, a first electronic structure disposed over the motherboard and having a control terminal and an output terminal, the first electronic structure comprising first linear conductive segments with a first serpentine conductive trace disposed within a first magnetic fill material; a second electronic structure over the motherboard and the second electronic structure having a control terminal and an output terminal, the output terminal of the second electronic structure coupled to the output terminal of the first electronic structure, the second electronic structure comprising second linear conductive segments and a second serpentine conductive trace disposed within a second magnetic fill material; a controller over the motherboard and the controller having output terminals coupled to the control terminals of the first electronic structure and the second electronic structure; and a chip over the motherboard and the chip having an input terminal coupled to the output terminals of the first electronic structure and the second electronic structure.

Example 18. The system of example 17, where the first electronic structure includes four chips, and where the coils of the first electronic structure are overlies the four chips.

Example 19. The system of example 17, where the first conductive segments have widths larger than a width of the first serpentine conductive trace.

Example 20. The system of example 17, where a terminal of the first serpentine conductive trace is coupled to a terminal of the second serpentine conductive trace.

The methods are illustrated and described above as a series of acts or events, but the illustrated ordering of such acts or events is not limiting. For example, some acts or events may occur in different orders and/or concurrently with other acts or events apart from those illustrated and/or described herein. Also, some illustrated acts or events are optional to implement one or more aspects or embodiments of this description. Further, one or more of the acts or events depicted herein may be performed in one or more separate acts and/or phases. In some embodiments, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are illustrated and/or described herein, other transistors (or equivalent switching devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT-e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/-10 percent of the stated value, or, if the value is zero, a reasonable range of values around zero. Modifications are possible in the described examples, and other implementations are possible, within the scope of the claims.

What is claimed is:

1. An electronic structure, comprising:
a substrate having a first row of contacts and a second row of contacts;
chips arranged in a first row and a second row on the substrate, the chips in the first row having output terminals coupled to the first row of contacts, and the chips in the second row having output terminals coupled to the second row of contacts;
first conductive segments extending away from a surface of the substrate and away from the first row of contacts;
second conductive segments extending away from the surface of the substrate and away from the second row of contacts;
third conductive segments extending from respective first conductive segments of the first conductive segments to respective second conductive segments of the second conductive segments, wherein respective third conductive segments of the third conductive segments include linear segments extending over the chips; and
a conductive trace over the chips and over or under the third conductive segments, wherein the conductive trace has a serpentine shape.

2. The electronic structure of claim 1, further comprising:
a first conductive segment extending between a first end of the conductive trace and a first contact on the substrate; and
a second conductive segment extending between a second end of the conductive trace and a second contact on the substrate.

3. The electronic structure of claim 1, further comprising a magnetic fill material at least partially surrounding the conductive trace.

4. The electronic structure of claim 1, wherein chips in the first row are offset in a first direction relative to chips in the second row.

5. The electronic structure of claim 1, wherein the first conductive segments, the second conductive segments, the third conductive segments, and the conductive trace each comprise copper.

6. The electronic structure of claim 1, wherein the serpentine shape of the conductive trace includes linear segments, and wherein the linear segments of the conductive trace are over or under the third conductive segments and are arranged in the same direction with the linear segments of the third conductive segments.

7. The electronic structure of claim 1, further comprising:
a first heat sink structure around the chips, the first conductive segments, the second conductive segments, the third conductive segments, and the conductive trace along a top surface, a first side surface, and a bottom surface; and
a second heat sink structure around the chips, the first conductive segments, the second conductive segments, the third conductive segments, and the conductive trace along the top surface, a second side surface opposite the first side surface, and the bottom surface.

8. The electronic structure of claim 1, wherein a number of conductive segments in the third conductive segments is equal to a number of chips.

9. A device comprising:
a substrate having a first edge and a second edge opposite the first edge;
a first row of power stage chips over the substrate, the first row of power stage chips having first output terminals that are adjacent to the first edge;
a second row of power stage chips between the first row of power stage chips and the second edge, the second row of power stage chips having second output terminals that are adjacent to the second edge;
first conductive bridges having respective base regions that are coupled to the first output terminals of the first row of power stage chips, the respective conductive bridges of the first conductive bridges extending over respective power stage chips of the first row; and
a second conductive bridges having respective base regions that are coupled to the second output terminals of the second row of power stage chips, the respective conductive bridges of the second conductive bridges extending over respective power stage chips of the second row.

10. The device of claim 9, wherein the first row of power stage chips extend in a first direction, and wherein the second row of power stage chips are staggered from the first row of power stage chips along the first direction.

11. The device of claim 9, wherein the first conductive bridges includes a first conductive bridge and a second conductive bridge, wherein the second conductive bridges includes a third conductive bridge, wherein the third conductive bridge is between the first conductive bridge and the second conductive bridge.

12. The device of claim 9, wherein the first conductive bridges and the second conductive bridges have lengths that are at least twice as long as a length of a power stage chip.

13. The device of claim 9, further comprising a serpentine trace positioned over the first conductive bridges and the second conductive bridges.

14. The device of claim 13, wherein the serpentine trace has conductive segments extending over or under the first conductive bridges and the second conductive bridges, and the conductive segments of the serpentine trace being arranged in a same direction with the first conductive bridges and the second conductive bridges.

15. The device of claim 13, further comprising a magnetic fill material around the first conductive bridges, the second conductive bridges, and the serpentine trace.

16. The device of claim 14, wherein the conductive segments of the serpentine trace have respective widths that are less than a width of the first conductive bridges.

17. A system comprising:
a motherboard;
a first electronic structure over the motherboard and having a control terminal and an output terminal, the first electronic structure comprising first linear conductive segments and a first serpentine conductive trace within a first magnetic fill material;
a second electronic structure over the motherboard and the second electronic structure having a control terminal and an output terminal, the output terminal of the second electronic structure coupled to the output terminal of the first electronic structure, the second electronic structure comprising second linear conductive segments and a second serpentine conductive trace within a second magnetic fill material;
a controller over the motherboard and the controller having output terminals coupled to the control terminals of the first electronic structure and the second electronic structure; and
a chip over the motherboard and the chip having an input terminal coupled to the output terminals of first electronic structure and the second electronic structure.

18. The system of claim 17, wherein the first electronic structure comprises four chips, and wherein the first serpentine conductive trace of the first electronic structure overlies the four chips.

19. The system of claim 17, wherein the first linear conductive segments have widths larger than a width of the first serpentine conductive trace.

20. The system of claim 17, wherein a terminal of the first serpentine conductive trace is coupled to a terminal of the second serpentine conductive trace.
